(19) United States
(12) Patent Application Publication
(10) Pub. No.: US 2005/0006690 A1
(43) Pub. Date: Jan. 13, 2005

(54) Capacitor of semiconductor device and method for fabricating the same

(76) Inventors: Sang Ho Woo, Gyeonggi-do (KR); Chang Rock Song, Gyeonggi-do (KR); Dong Su Park, Gyeonggi-do (KR); Cheol Hwan Park, Seoul (KR); Tae Hyeok Lee, Gyeonggi-do (KR)

Correspondence Address: HELLER EHRMAN WHITE & MCAULIFFE LLP, 1666 K STREET,NW, SUITE 300, WASHINGTON, DC, 20006, US

(21) Appl. No.: 10/608,485

(22) Filed: Jun. 30, 2003

(30) Foreign Application Priority Data
Dec. 31, 2002 (KR) 10-2002-0088115

(51) Int. Cl. H01L 21/8242; H01L 27/108; H01L 29/76; H01L 31/119; H01L 21/20

(52) U.S. Cl. 257/310; 438/240; 438/250; 438/393

(57) ABSTRACT

A capacitor of a semiconductor device, and a method for fabricating the same, wherein the thickness of the dielectric film is reduced and the formation of the dielectric film is performed at a low temperature to prevent oxidation of the storage electrode are disclosed. The method for fabricating a capacitor of a semiconductor device comprises the steps of: forming a storage electrode using silicon; sequentially depositing a first Al₂O₃ film, a Ta₂O₅ layer doped with Ti, and a second Al₂O₃ film on the storage electrode to form a dielectric film; and forming a plate electrode on the dielectric film using metal. The capacitor of a semiconductor device comprises a storage electrode comprising silicon; a dielectric film disposed on the storage electrode, the dielectric film including a stacked structure of a first Al₂O₃ film, a Ta₂O₅ layer doped with Ti, and a second Al₂O₃ film; and a metal plate electrode disposed on the dielectric film.

### BACKGROUND OF THE INVENTION

1. Field of the Invention

The present invention relates to a capacitor of a semiconductor device, and a method for fabricating the same, wherein the thickness of the dielectric film is reduced and the formation of the dielectric film is performed at a low temperature to prevent oxidation of the storage electrode, thereby improving the yield and the reliability of the capacitor of semiconductor device.

2. Description of the Prior Art

Generally, a capacitor of a DRAM stores a predetermined amount of charges for reading and writing data. Therefore, a capacitor must have sufficient capacitance, and the dielectric film used in the capacitor must have excellent leakage current characteristics, to provide long term reliability for its repeated usage.

The capacitance of a capacitor is proportional to the surface area of an electrode, and inversely proportional to the thickness of a dielectric film. However, as the size of a cell decreases due to a high integration density of a semiconductor device, it becomes more difficult to obtain sufficient capacitance. In order to obtain sufficient capacitance, the height of a capacitor is increased, and the process margin between adjacent cells is decreased.

A conventional capacitor of a semiconductor device has a silicon/insulator/silicon (“SIS”) structure in which storage and plate electrodes are manufactured using doped silicon, and the insulating layer includes a stacked structure of oxide film/nitride film/oxide film (“ONO”), although the lower oxide film is not essential.

A conventional method for fabricating a capacitor of a semiconductor device is as follows.

A lower structure is formed on a semiconductor device by performing predetermined processes. Thereafter, a storage electrode is formed using silicon layer and then natural oxide on the storage electrode is cleaned using HF solution. A low pressure chemical vapor deposition (‘LPCVD’) is performed to form a nitride film on the storage electrode and a surface of the nitride film is then oxidized to form an oxide film. Next, a plate electrode is formed thereon using silicon layer. The nitride film is a Si₃N₄ or SiO_{X}N_{Y} film.

When a capacitor is manufactured by the conventional method for fabricating a capacitor of a semiconductor device, the capacitor does not provide sufficient capacitance due to reduced cell area for increasing the degree of integration. A method for reducing equivalent oxide thickness of the dielectric film to increase capacitance has been proposed. However, since the oxidation resistance of a nitride film is drastically decreased when the thickness of the nitride film is less than 40 Å, the storage electrode or bit line is oxidized in the subsequent process. When the thickness of the nitride film is less than 50 Å, leakage current is increased and breakdown voltage is decreased. Therefore, the nitride film cannot be formed to have a thickness of less than 45 Å.

### SUMMARY OF THE INVENTION

It is an object of the present invention to provide a method for fabricating a capacitor of a semiconductor device, comprising the steps of: forming a storage electrode using silicon; sequentially depositing a first Al₂O₃ film, a Ta₂O₅ layer doped with Ti, and a second Al₂O₃ film on the storage electrode to form a dielectric film; and forming a plate electrode on the dielectric film using metal.

It is another object of the present invention to provide a capacitor of a semiconductor device comprising a storage electrode comprising silicon; a dielectric film disposed on the storage electrode, the dielectric film including a stacked structure of a first Al₂O₃ film, a Ta₂O₅ layer doped with Ti, and a second Al₂O₃ film; and a metal plate electrode disposed on the dielectric film.

### BRIEF DESCRIPTION OF THE DRAWINGS

FIG. 1 is a cross-sectional diagram illustrating a capacitor of a semiconductor device in accordance with the present invention.

### DETAILED DESCRIPTION OF THE PREFERRED EMBODIMENTS

The present invention will be described in detail with reference to the accompanying drawings.

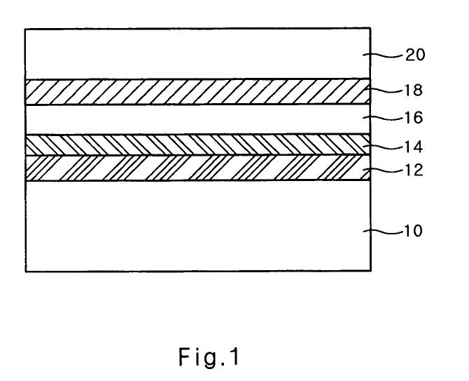

FIG. 1 is a cross-sectional diagram illustrating a capacitor of a semiconductor device in accordance with the present invention. The capacitor shown in FIG. 1 has a metal/insulator/silicon (MIS) structure.

A storage electrode 12 is formed on a interlayer insulating film 10 having a predetermined lower structure, preferably using CVD method. A hemispherical silicon layer may be formed on the surface area of the storage electrode 12 to increase surface area. Thereafter, a first Al₂O₃ film 14, a Ta₂O₅ layer 16 doped with Ti, and a second Al₂O₃ film 18, having a thickness of 5-100 Å respectively, are sequentially formed on the storage electrode 12. Preferably, the first Al₂O₃ film 14 and the second Al₂O₃ film 18 are formed by performing LPCVD process, atomic layer deposition (“ALD”) process or plasma enhanced CVD (“PECVD”) process. The thickness of the second Al₂O₃ film 18 is determined by considering material and thickness of a plate electrode formed in a subsequent process. The Ta₂O₅ layer 16 doped with Ti is formed using a cocktail source containing 1-50% of a Ti source for in-situ Ti doping. O₂ gas may be used during the deposition process of the Ta₂O₅ layer 16 to improve characteristics thereof. An ALD process, a metal organic CVD (“MOCVD”) process or a PECVD process may be used for the formation of the Ta₂O₅ layer 16.

Thereafter, a plate electrode is formed on the second Al₂O₃ film 18 using TiN film or Ru film.

Since the plate electrode is formed using metal, depletion region is not formed due to high work function of the metal. Therefore, an effective thickness of the dielectric film is maintained below 30 Å, and oxidation process may be performed using NO, O₂ or N₂O gas or under low pressure to prevent oxidation of the storage electrode.

As discussed above, in accordance with the method for fabricating a capacitor of a semiconductor device, the storage electrode, the dielectric film and plate electrode are formed using silicon, a stacked structure of a first Al₂O₃ film, a Ta₂O₅ layer and a second Al₂O₃ film, and metal, respectively, so that the effective thickness of the dielectric film is maintained below 30 Å due to high work function of the metal and oxidation of the storage electrode is prevented to improve yield and reliability of the device.

1. A method for fabricating a capacitor of a semiconductor device, comprising the steps of:
forming a storage electrode using silicon;
sequentially depositing a first Al₂O₃ film, a Ta₂O₅ layer doped with Ti, and a second Al₂O₃ film on the storage electrode to form a dielectric film; and
forming a plate electrode on the dielectric film using metal.

2. The method according to claim 1, wherein the first Al₂O₃ film and the second Al₂O₃ film is formed in a LPCVD process, an ALD process or a PECVD process.

3. The method according to claim 1, the first Al₂O₃ film, the Ta₂O₅ layer doped with Ti, and the second Al₂O₃ film have a thickness ranging from 5 to 100 Å, respectively.

4. The method according to claim 1, wherein the Ta₂O₅ layer doped with Ti is formed using a cocktail source containing 1-50% of a Ti source in an in-situ doping process.

5. The method according to claim 4, wherein the in-situ doping process is performed using a mixture of the cocktail source and O₂ gas.

6. The method according to claim 1, wherein the Ta₂O₅ layer doped with Ti is formed in an ALD process, an MOCVD process or a PECVD process.

7. A capacitor of a semiconductor device, comprising:
a storage electrode comprising silicon;
a dielectric film disposed on the storage electrode, the dielectric film including a stacked structure of a first Al₂O₃ film, a Ta₂O₅ layer doped with Ti, and a second Al₂O₃ film; and
a metal plate electrode disposed on the dielectric film.
